(19) United States
(12) Patent Application Publication
(10) Pub. No.: US 2023/0056204 A1
(43) Pub. Date: Feb. 23, 2023

(54) SEMICONDUCTOR STRUCTURE AND METHOD FOR MANUFACTURING SAME

(71) Applicant: CHANGXIN MEMORY TECHNOLOGIES, INC., Hefei City, Anhui (CN)

(72) Inventors: Longyang CHEN, Hefei City, Anhui (CN); Gongyi WU, Hefei City, Anhui (CN)

(21) Appl. No.: 17/441,182

(22) PCT Filed: Jun. 30, 2021
(86) PCT No.: PCT/CN2021/103826

§ 371 Date: Sep. 20, 2021

(30) Foreign Application Priority Data
Aug. 25, 2020 (CN) 202010864006.9

(51) Int. Cl. H01L 27/108; H01L 23/528

(52) U.S. Cl. CPC H01L 27/10885; H01L 27/10814; H01L 27/10855; H01L 27/10888; H01L 23/5283

(57) ABSTRACT

Embodiments of the present disclosure provide a semiconductor structure and a method for manufacturing the same. The semiconductor structure includes: a substrate and a plurality of discrete bit line structures disposed on the substrate, a conductive plug being arranged between each adjacent bit line structures, a top surface of the conductive plug being lower than or flush with top surfaces of the bit line structures; and landing pads, one of the landing pads covering at least the top surface and part of side wall surfaces of the conductive plug.

### CROSS-REFERENCE TO RELATED APPLICATIONS

The present disclosure is a national stage entry of International Application No. PCT/CN2021/103826, filed on Jun. 30, 2021, which claims the priority to Chinese Patent Application 202010864006.9, titled “SEMICONDUCTOR STRUCTURE AND METHOD FOR MANUFACTURING SAME”, filed to the CNIPA on Aug. 25, 2020. International Application No. PCT/CN2021/103826 and Chinese Patent Application 202010864006.9 are incorporated herein by reference in their entireties.

### TECHNICAL FIELD

The present disclosure relates to, but is not limited to, a semiconductor structure and a method for manufacturing the same.

### BACKGROUND

The development of dynamic memories pursues the characteristics of high speed, high integration density, low power consumption, etc. However, due to the miniaturization of semiconductor structures, the structural characteristics between different conductive structures are changed, which further affects the electrical characteristics of the semiconductor structures, so that the semiconductor structures cannot meet the preset performance requirements.

For example, the contact area between adjacent conductive structures decreases, the contact resistance increases, the signal transmission quality deteriorates, and the power consumption increases; the spacing between adjacent conductive structures decreases, the parasitic capacitance between adjacent conductive structures increases, and the signal transmission rate of the conductive structures slows down.

### SUMMARY

The following is the summary of subject matters detailed in the present disclosure. The summary is not intended to limit the protection scope of the claims.

On the one hand, an embodiment of the present disclosure provides a semiconductor structure, including: a substrate and a plurality of discrete bit line structures disposed on the substrate, a conductive plug being arranged between each adjacent bit line structures, a top surface of the conductive plug being lower than or flush with top surfaces of the bit line structures; and landing pads, one of the landing pads covering at least the top surface and part of side wall surfaces of the conductive plug.

On the other hand, an embodiment of the present disclosure further provides a method for manufacturing a semiconductor structure, including: providing a substrate and a plurality of discrete bit line structures disposed on the substrate, a conductive plug being arranged between each adjacent bit line structures, a top surface of the conductive plug being lower than or flush with top surfaces of the bit line structures; exposing part of side wall surfaces of the conductive plug; and forming landing pads, one of the landing pads covering at least the top surface and part of the side wall surfaces of the conductive plug.

Other aspects will be apparent upon reading and understanding the accompanying drawings and detailed descriptions.

### BRIEF DESCRIPTION OF THE DRAWINGS

One or more embodiments are exemplified by corresponding drawings. These exemplified descriptions do not constitute limitations on the embodiments. The elements with the same reference numerals in the drawings are denoted as similar elements. Unless otherwise stated, the drawings do not constitute proportional limitations. For those skilled in the art, other drawings may be obtained based on these drawings without any creative efforts.

FIG. 1 is a schematic diagram of a cross-sectional structure of a substrate and initial bit line structures according to an embodiment of the present disclosure;

FIG. 2 is a schematic diagram of a cross-sectional structure of a semiconductor structure formed with an isolation side wall film according to an embodiment of the present disclosure;

FIG. 3 is a schematic diagram of a cross-sectional structure of a semiconductor structure formed with a conductive plug according to an embodiment of the present disclosure;

FIG. 4 is a schematic diagram of a cross-sectional structure of a semiconductor structure formed with a landing pad according to an embodiment of the present disclosure;

FIG. 5 is a schematic diagram of a cross-sectional structure of a substrate and initial bit line structures according to an embodiment of the present disclosure;

FIG. 6 is a schematic diagram of a cross-sectional structure of a semiconductor structure deposited with a first side wall film according to an embodiment of the present disclosure;

FIG. 7 is a schematic diagram of a cross-sectional structure of a semiconductor structure deposited with a first sacrificial film according to an embodiment of the present disclosure;

FIG. 8 is a schematic diagram of a cross-sectional structure of a semiconductor structure formed with a first sacrificial layer according to an embodiment of the present disclosure;

FIG. 9 is a schematic diagram of a cross-sectional structure of a semiconductor structure formed with initial isolation side walls according to an embodiment of the present disclosure;

FIG. 10 is a top view of a semiconductor structure deposited with a second sacrificial layer according to an embodiment of the present disclosure;

FIG. 11 is a schematic diagram of a cross-sectional structure of part X-X in FIG. 10;

FIG. 12 is a schematic diagram of a cross-sectional structure of part Y-Y in FIG. 10;

FIG. 13 is a schematic diagram of a cross-sectional structure of a semiconductor structure formed with bit line isolation trenches according to an embodiment of the present disclosure;

FIG. 14 is a schematic diagram of a cross-sectional structure of a semiconductor structure formed with bit line isolation trenches according to an embodiment of the present disclosure;

FIG. 15 is a schematic diagram of a cross-sectional structure of a semiconductor structure formed with a bit line isolation film according to an embodiment of the present disclosure;

FIG. 16 is a schematic diagram of a cross-sectional structure of a semiconductor structure formed with a bit line isolation film according to an embodiment of the present disclosure;

FIG. 17 is a schematic diagram of a cross-sectional structure of a semiconductor structure from which the second sacrificial layer and the bit line isolation film on the top of the second sacrificial layer are removed according to an embodiment of the present disclosure;

FIG. 18 is a schematic diagram of a cross-sectional structure of a semiconductor structure from which the second sacrificial layer and the bit line isolation film on the top of the second sacrificial layer are removed according to an embodiment of the present disclosure;

FIG. 19 is a schematic diagram of a cross-sectional structure of a semiconductor structure formed with capacitor contact holes according to an embodiment of the present disclosure;

FIG. 20 is a schematic diagram of a cross-sectional structure of a semiconductor structure formed with a conductive film according to an embodiment of the present disclosure;

FIG. 21 is a schematic diagram of a cross-sectional structure of a semiconductor structure formed with a conductive plug according to an embodiment of the present disclosure;

FIG. 22 is a schematic diagram of a cross-sectional structure of a semiconductor structure where the initial bit line structures and the initial isolation side walls are etched back according to an embodiment of the present disclosure;

FIG. 23 is a schematic diagram of a cross-sectional structure of a semiconductor structure formed with a top isolation film according to an embodiment of the present disclosure;

FIG. 24 is a schematic diagram of a cross-sectional structure of a semiconductor structure patterned with a second mask layer according to an embodiment of the present disclosure;

FIG. 25 is a schematic diagram of a cross-sectional structure of a semiconductor structure patterned with a top isolation layer according to an embodiment of the present disclosure;

FIG. 26 is a schematic diagram of a cross-sectional structure of a semiconductor structure patterned with a landing film according to an embodiment of the present disclosure;

FIG. 27 is a schematic diagram of a cross-sectional structure of a semiconductor structure patterned with a third mask layer according to an embodiment of the present disclosure;

FIG. 28 is a schematic diagram of a cross-sectional structure of a semiconductor structure patterned with a landing pad according to an embodiment of the present disclosure.

### DETAILED DESCRIPTION

In order to make the objectives, technical solutions and advantages of the embodiments of the present disclosure clearer, the embodiments of the present disclosure will be described in detail below with reference to the accompanying drawings. However, those skilled in the art can understand that, in each embodiment of the present disclosure, many technical details are proposed in order to enable a reader to better understand the present application. However, the technical solutions of the present application can also be implemented without these technical details and various variations and modifications based on the following embodiments.

How to improve the electrical performance of dynamic memories under miniature sizes is the focus of current research.

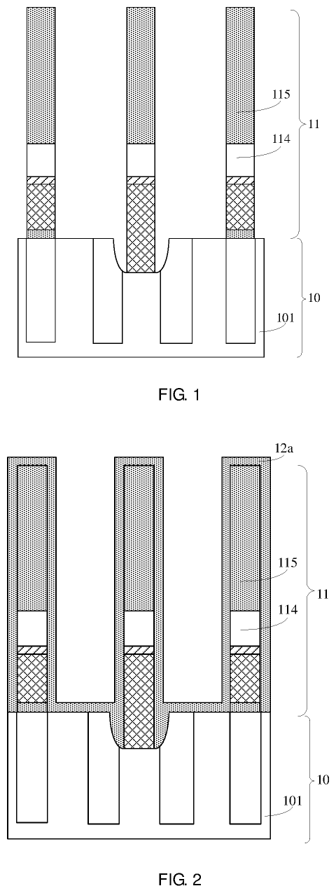

Referring to FIG. 1, a substrate 10 and a plurality of discrete initial bit line structures 11 on the substrate 10 are provided.

The initial bit line structure 11 includes a metal conductive layer 114 and a top dielectric layer 115. In a direction perpendicular to the surface of the substrate 10, the top dielectric layer 115 has a thickness greater than 140 nm. Because of the relatively thick top dielectric layer 115 and the initial bit line structure 11 with relatively large height-width ratio, the initial bit line structure 11 have poor structural stability, and are prone to tipping or collapse spontaneously or under stress.

Referring to FIG. 2, an isolation side wall film 12a is formed, the isolation side wall film 12a being used to form an isolation side wall.

The isolation side wall is not only used to isolate the metal conductive layer 114 and a conductive plug subsequently formed, but also used to support the initial bit line structure 11 to a certain extent. Therefore, silicon nitride with relatively high hardness is usually selected as the material of the isolation side wall film 12a. However, the silicon nitride has a relatively high dielectric constant. Under the condition that the size of the semiconductor structure is miniaturized, the silicon nitride as an isolation material will cause a relatively large parasitic capacitance between the metal conductive layer 114 and the conductive plug, so that the signal transmission rate of the metal conductive layer 114 and the conductive plug will be greatly affected.

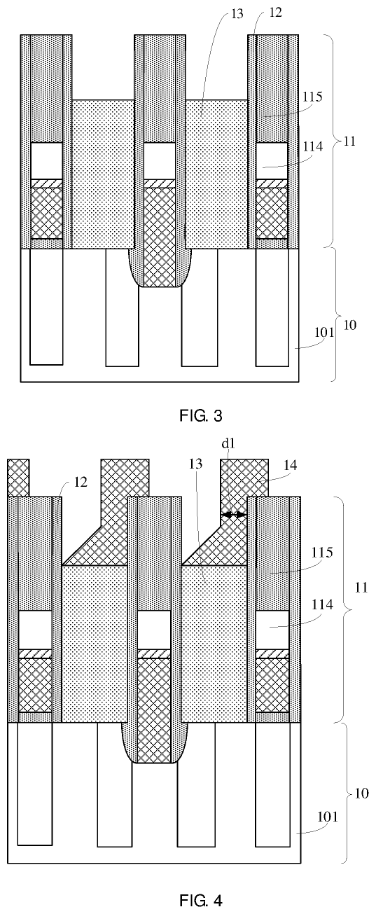

Referring to FIG. 3, the isolation side wall film 12a is etched to form an isolation side wall 12 and reduce the thickness of the top dielectric layer 115; and a conductive plug 13 is filled between each adjacent initial bit line structures 11, a top surface of the conductive plug 13 being lower than a top surface of the initial bit line structure 11.

In order to make the initial bit line structure 11 have better structural stability, the top dielectric layer 115 is usually thinned when it is too thick. The top dielectric layer 115 is usually thinned by a planarization process in one step. During the planarization process, the initial bit line structure 11 will be subjected to stress from grinding equipment. Under the stress, the initial bit line structure 11 is more likely to tip or collapse. In addition, the possibility that the initial bit line structure 11 tips or collapses is also related to the process time of the planarization process. The longer the process time is, the greater the influence of the stress on the initial bit line structure 11 is, and the more likely the initial bit line structure 11 tips or collapses.

The process time of the planarization process is related to the thickness of the top dielectric layer 115 that needs to be reduced. The thicker the top dielectric layer 115 that needs to be cut is, the longer the process time is.

Referring to FIG. 4, a landing pad 14 is formed.

Since the top surface of the conductive plug 13 is lower than the top surface of the initial bit line structure 11, the landing pad 14 can only cover the top surface of the conductive plug 13; and as the size of the semiconductor structure is miniaturized, the area of the top surface of the conductive plug 13 gradually decreases, the contact area between the conductive plug 13 and the landing pad 14 decreases, and the contact resistance increases, resulting in deterioration of signal transmission quality and increase of transmission power consumption.

In addition, in order to avoid too small spacing between each adjacent landing pads 14 to generate a relatively large parasitic capacitance, the side wall of the landing pad 14 may be further etched to increase the spacing between adjacent landing pads 14. However, this solution will reduce the minimum width d1 of the landing pad 14 on the signal transmission path, which in turn increases the parasitic resistance of the landing pad 14 itself, resulting in deterioration of signal transmission quality and increase in transmission power consumption.

The embodiments of the present disclosure provide a semiconductor structure and a method for manufacturing the same, in which the landing pads not only cover the top surfaces of the conductive plug, but also cover part of the side wall surfaces of the conductive plug, thereby increasing the contact area between the conductive plug and the landing pads, reducing the contact resistance, then improving the signal transmission quality and reducing the corresponding power consumption.

FIGS. 5 to 28 are schematic structure diagrams corresponding to various steps of the method for manufacturing a semiconductor structure according to the embodiments of the present disclosure.

Referring to FIG. 5, a substrate 20 and a plurality of discrete initial bit line structures 21 on the substrate 20 are provided.

The substrate 20 includes isolation structures 202 and active area 201 between adjacent isolation structures 202, and the initial bit line structures 21 are exposed on surfaces of the active area 201.

The initial bit line structure 21 includes a bottom dielectric layer 211, a bit line contact layer 212, a barrier layer 213, a metal conductive layer 214, and a top dielectric layer 215. In a direction perpendicular to the surface of the substrate 20, the top dielectric layer 215 has a thickness of 20 nm to 100 nm, for example, 30 nm, 50 nm, or 70 nm. The thickness of the top dielectric layer 215 within this numerical range ensures that the top dielectric layer 215 has a good isolation effect, and avoids tipping or collapse of the initial bit line structure 21 due to excessive height-width ratio.

The current top dielectric layer 215 may be obtained by a planarization process, and the current thickness of the top dielectric layer 215 is not its final thickness. Because the top dielectric layer 215 needs to be etched later, the final thickness of the top dielectric layer 215 will actually be smaller. Accordingly, because of the subsequent etching process, the current thickness of the top dielectric layer 215 may be greater than the actually required thickness of the top dielectric layer 215, thereby shortening the planarization time required to form the initial bit line structure 21 and avoiding tipping or collapse of the initial bit line structure 21 due to too long planarization time.

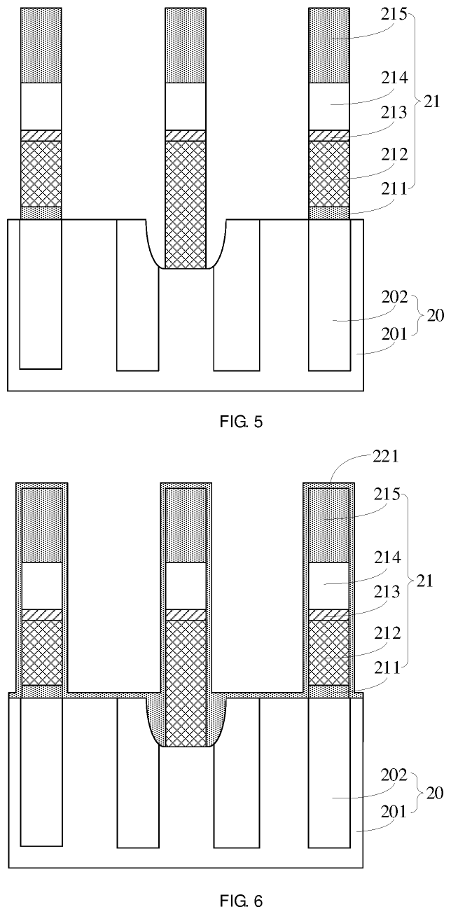

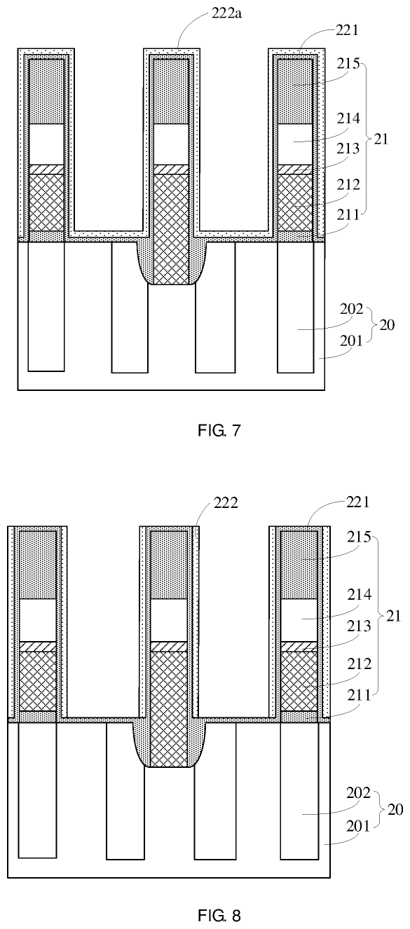

Referring to FIGS. 6 and 7, a first side wall film 221 and a first sacrificial film 222a are sequentially deposited.

The first side wall film 221 and the first sacrificial film 222a are deposited by atomic layer deposition.

The material of the first side wall film 221 may have a relatively high hardness, so that the isolation side wall formed subsequently can support the initial bit line structure 21 to a certain extent, and the material of the first side wall film 221 includes silicon nitride. The material of the first sacrificial film 222a may have a higher etching selection ratio than the material of the first side wall film 221, thereby avoiding damage to the first side wall film 221 when the first sacrificial film 222a is etched, and ensuring that the isolation side wall formed subsequently has better structural integrity and better isolation effect. The material of the first sacrificial film 222a includes a photoresist or silicon dioxide.

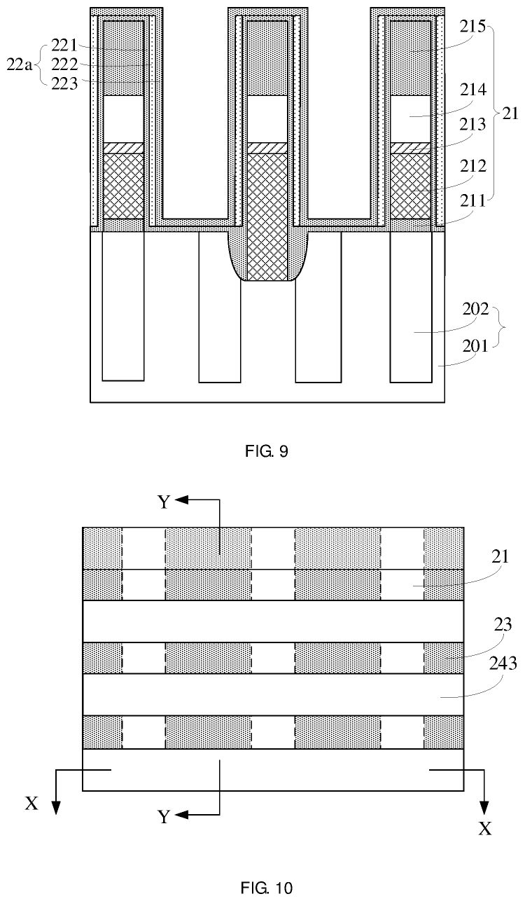

Referring to FIGS. 8 and 9, part of the first sacrificial film 222a (refer to FIG. 7) is removed to form a first sacrificial layer 222; a second side wall film 223 is deposited, wherein the first side wall film 221, the first sacrificial layer 222 and the second side wall film 223 constitute an initial isolation side wall 22a.

The first sacrificial film 222a on the top of the initial bit line structure 21 and the bottom of a groove between the adjacent initial bit line structures 21 is removed to form a first sacrificial layer 222. The material of the second side wall film 223 may be the same as or different from that of the first side wall film 221, and the process of forming the second side wall film 223 may be the same or different from that of forming the first side wall film 221.

After the initial isolation side wall 22a is formed, a bit line isolation layer needs to be formed, so that the groove between the adjacent initial bit line structures 21 is segmented into a plurality of capacitor contact holes. The specific process steps for forming the bit line isolation layer are as follows:

Referring to FIGS. 10 to 12, a second sacrificial layer 23 is deposited, and a first mask layer 241 is formed on a top surface of the second sacrificial layer 23.

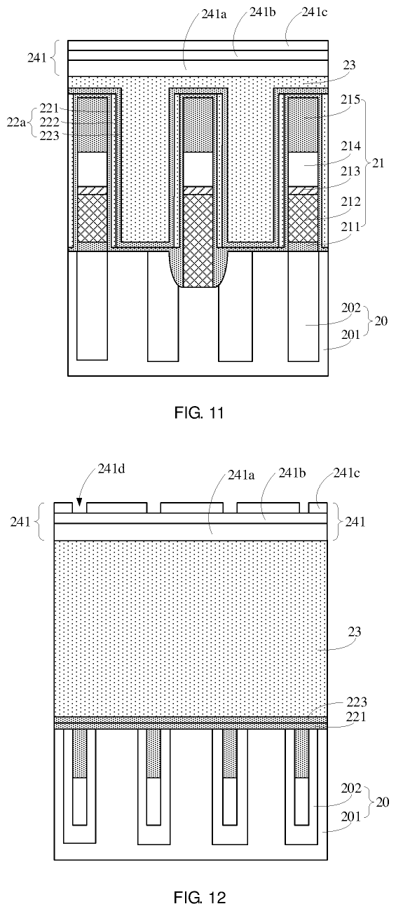

FIG. 10 is a top view of the semiconductor structure formed in this step; FIG. 11 is a schematic diagram of a cross-sectional structure of the semiconductor structure shown in FIG. 10 along a first cross-sectional direction XX; FIG. 12 is a schematic diagram of a cross-sectional structure of the semiconductor structure shown in FIG. 10 along a second cross-sectional direction YY.

The first mask layer 241 includes a first sub-mask layer 241a, a second sub-mask layer 241b and a third sub-mask layer 241c that are sequentially stacked, and the third sub-mask layer 241c has a first opening 241d.

In some embodiments of the present disclosure, the second sacrificial layer 23 is located between adjacent initial bit line structures 21 and covers the top surface of the initial isolation side wall 22a, and the first opening 241d is used to define the position of the bit line isolation layer formed subsequently. In other embodiments, the second sacrificial layer 23 is flush with the top surface of the initial isolation side wall 22a.

In some embodiments of the present disclosure, the material of the first sub-mask layer 241a includes titanium nitride, the material of the second sub-mask layer 241b includes silicon nitride, and the material of the third sub-mask layer 241c includes a photoresist.

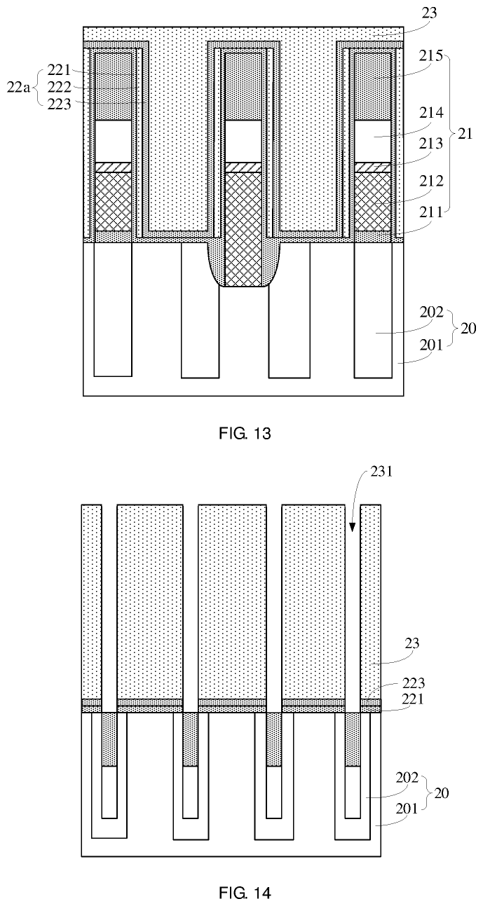

Referring to FIGS. 13 and 14, etching is performed layer by layer through the first opening 241d, to form a bit line isolation trench 231 in the second sacrificial layer 23 for filling a dielectric material.

In some embodiments of the present disclosure, the bit line isolation trench 231 penetrates the first side wall film 221 and the second side wall film 223, and exposes the active area 201 in the substrate 20, which ensures the bit line isolation layer formed subsequently is of an integrated structure, and then ensures that the bit line isolation layer has good structural stability. In other embodiments, the bit line isolation trench exposes the second side wall film on the surface of the substrate, and the bit line isolation layer formed subsequently includes a part of the first side wall film and a part of the second side wall film between the bit line isolation trench and the substrate.

After the bit line isolation trench 231 is formed, the first mask layer 241 is removed (refer to FIG. 12).

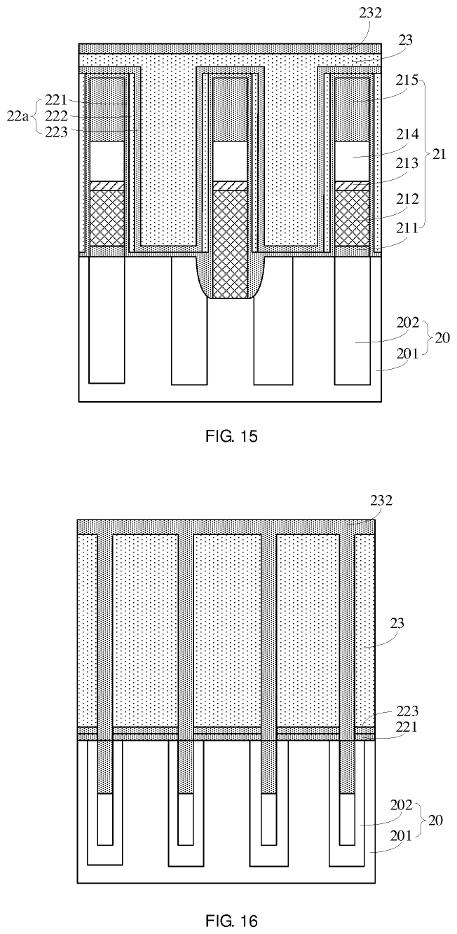

Referring to FIGS. 15 and 16, a dielectric material is filled to form a bit line isolation film 232.

The material of the bit line isolation film 232 may be the same as or different from that of the second side wall film 223. When the material of the bit line isolation film 232 is the same as that of the second side wall film 223, an etchant is subsequently used to etch and remove the second sacrificial layer 23. As such, only the etching selection ratio of the material of the second sacrificial layer 23 to the single material, that is, the material of the bit line isolation film 232 under the same etching process needs to be considered. In this way, the selectable range of the etchant for the second sacrificial layer 23 is increased.

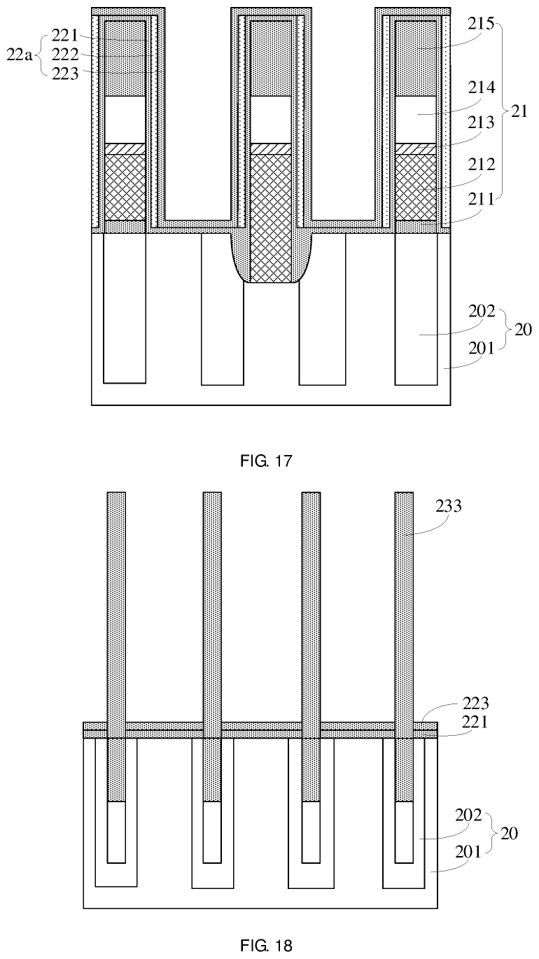

Referring to FIGS. 17 and 18, the bit line isolation film 232 (refer to FIG. 16) on the top of the second sacrificial layer 23 (refer to FIG. 16) is removed to form a bit line isolation layer 233; and the second sacrificial layer 23 is removed.

In some embodiments of the present disclosure, the bit line isolation film 232 on the top of the second sacrificial layer 23 is removed by a planarization process, and the remaining bit line isolation film 232 serves as the bit line isolation layer 233. In other embodiments, the bit line isolation film covering the second sacrificial layer may be removed alone with a mask.

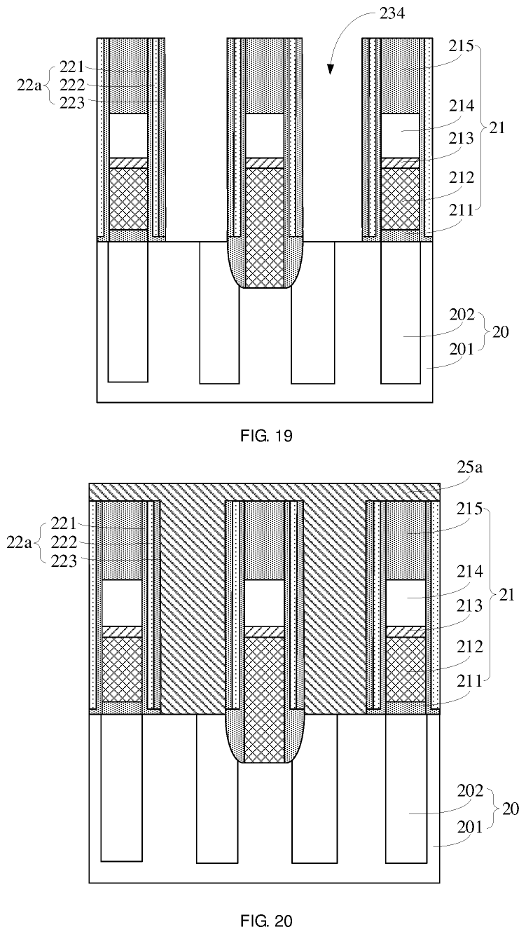

Referring to FIG. 19, a capacitor contact hole 234 is formed.

In some embodiments of the present disclosure, the first side wall film 221 and the second side wall film 223 at the bottom of the groove between the adjacent initial bit line structures 21 are removed to expose the active area 201 and form the capacitor contact hole 234.

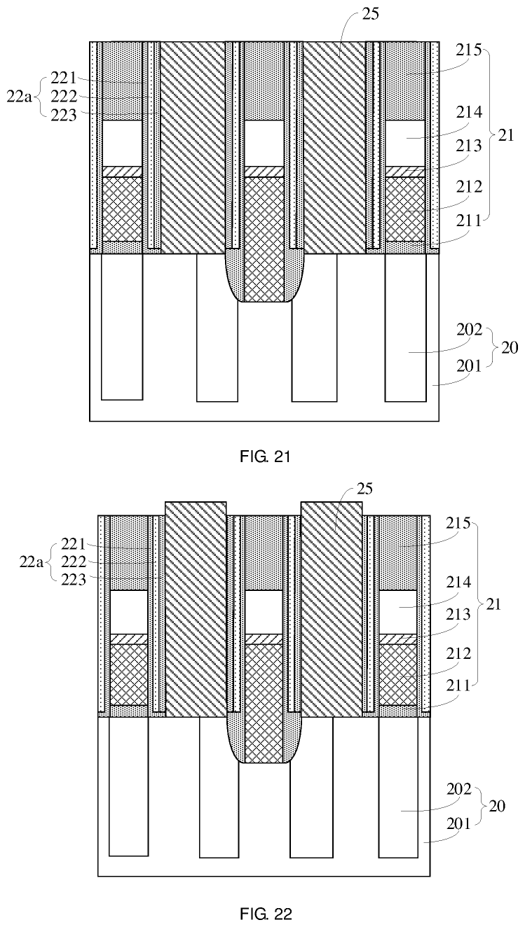

Referring to FIGS. 20 and 21, a conductive plug 25 is formed.

The capacitor contact hole 234 (refer to FIG. 19) is filled with conductive material to form a conductive film 25a; and the conductive film 25a is planarized to form the conductive plug 25, a top surface of the conductive plug 25 being flush with top surfaces of the initial bit line structure 21 and the initial isolation side wall 22a.

Referring to FIG. 22, back etching is performed.

The initial bit line structure 21 and the initial isolation side wall 22a are etched back, so that the top surface of the initial bit line structure 21 and the top surface of the initial isolation side wall 22a are lower than the top surface of the conductive plug 25 to form a height difference, which avoids damage to the structure of the isolation side wall when the top isolation layer is etched subsequently to expose part of the side wall surfaces of the conductive plug 25.

Compared with increasing the height of the conductive plug 25 to form a height difference, the height difference formed by back etching enables the top dielectric layer 215 provided initially to have a relatively large thickness, so as to control the process time of the planarization process for forming the top dielectric layer 215 within a reasonable range, which then avoids tipping or collapse of the initial bit line structure 21 due to too long process time.

The initial bit line structure 21 is etched back, which is beneficial to reducing the thickness of the top dielectric layer 215, so that the thickness of the finally formed bit line structure meets the preset requirements and the finally formed bit line structure has better structural stability.

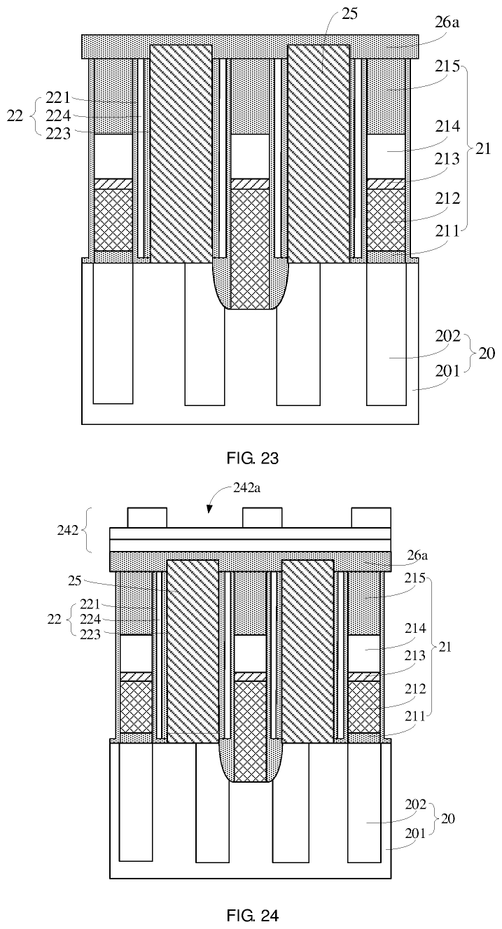

Referring to FIG. 23, the first sacrificial layer 222 (refer to FIG. 22) is removed to form an air gap 224; and a top isolation film 26a that blocks a top opening of the air gap 224 is formed.

The first side wall film 221, the air gap 224 and the second side wall film 223 constitute an isolation side wall 22.

In some embodiments of the present disclosure, the top surface of the top isolation film 26a is higher than the top surface of the conductive plug 25. In other embodiments, the top surface of the top isolation film is flush with the top surface of the conductive plug.

When the top surface of the top isolation film 26a is higher than the top surface of the conductive plug 25, the top surface of the subsequently formed top isolation layer is higher than the top surface of the conductive plug 25, and the top surface of the bit line structure including the top isolation layer is higher than that of the conductive plug 25. As such, the finally formed landing pad is in effective contact with the conductive plug 25 to avoid the reduction of the contact area caused by etching errors, so that the landing pad and the conductive plug 25 have good conductive characteristics.

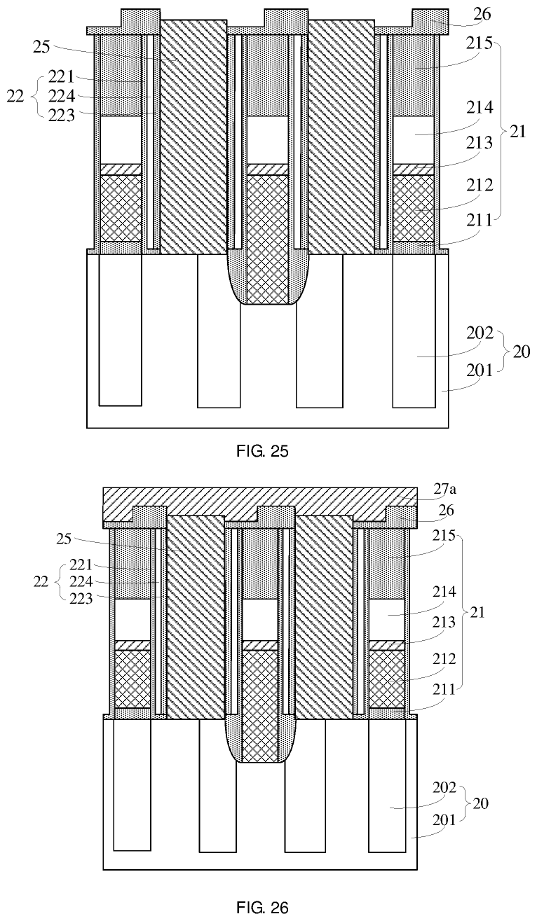

Referring to FIGS. 24 and 25, a second mask layer 242 is formed; and the top isolation film 26a is etched through the second mask layer 242 to form a top isolation layer 26.

The second mask layer 242 is different from the first mask layer 241 (refer to FIG. 12) only in the position of an opening pattern.

In some embodiments of the present disclosure, the second mask layer 242 has a second opening 242a. In the direction perpendicular to the surface of the substrate 20, the orthographic projection of the conductive plug 25 is located within the orthographic projection of the second opening 242a, and the projection of part of the top isolation film 26a between adjacent conductive plugs 25 is located within the orthographic projection of the second opening 242a. As such, the top isolation layer 26 exposing the top surface and part of the side wall surfaces of the conductive plug 25 can be formed by etching through the second mask layer 242, and the top surface of the conductive plug 25 is lower than that of the top isolation layer 26.

In some embodiments of the present disclosure, in the direction perpendicular to the surface of the substrate 20, the orthographic projection of the isolation side wall 22 is located within the orthographic projection of the second opening 242a, and the orthographic projection of the initial bit line structure 21 partially overlaps the orthographic projection of the second opening 242a. In other embodiments, the orthographic projection of the isolation side wall overlaps the orthographic projection of the second opening partially or at the boundary.

In some embodiments of the present disclosure, since there is an air gap 224 is provided in the isolation side wall 22, the isolation side wall 22 is not etched by the etching process, thereby avoiding exposing the air gap 224, preventing impurities from falling into the air gap 224, and ensuring that the isolation side wall 22 has a better isolation effect.

In some embodiments of the present disclosure, the conductive plug 25 is a quadrangular prism, and the top isolation layer 26 only exposes part of a surface of one side wall, which prevents the landing pad from occupying a too large plane position in a direction parallel to the surface of the substrate 20, and then ensures that other structures can be normally placed. In other embodiments, the top isolation layer may expose part of the surface of a plurality of side walls.

Referring to FIG. 26, a landing film 27a is formed.

In some embodiments of the present disclosure, the top surface of the landing film 27a is higher than the top surface of the top isolation layer 26. As such, the top isolation layer 26 is prevented from being damaged by the subsequent process of removing a third mask layer, and large stress is prevented from being applied to the top isolation layer 26 by the removing process, thereby ensuring that the top isolation layer 26 and the bit line structure including the top isolation layer 26 have good structural characteristics.

In other embodiments, the top surface of the landing film is lower than or flush with that of the top isolation layer.

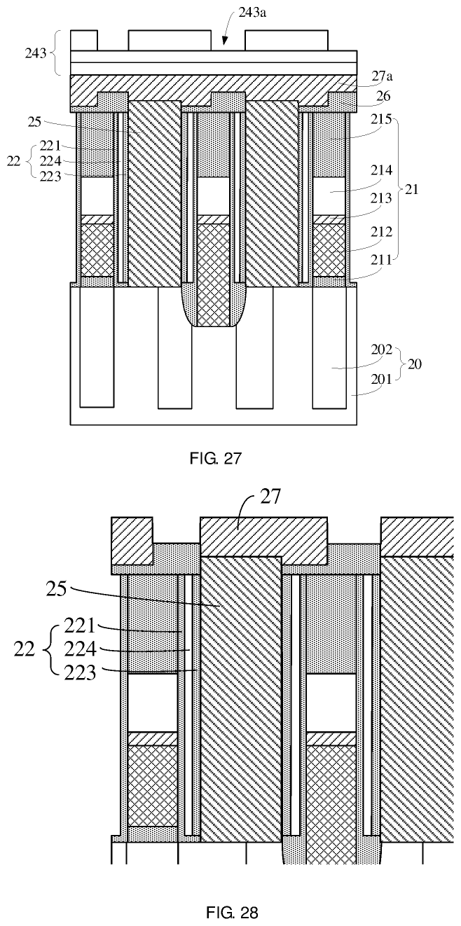

Referring to FIGS. 27 and 28, a landing pad 27 is formed.

A third mask layer 243 is formed. The third mask layer 243 is different from the first mask layer 241 (refer to FIG. 12) only in the position of an opening pattern.

After the third mask layer 243 is formed, the landing film 27a is etched through a third opening 243a of the third mask layer 243 to form the landing pad 27.

In some embodiments of the present disclosure, the landing pad not only covers the top surface of the conductive plug, but also covers part of the side wall surfaces of the conductive plug, which is beneficial to increasing the contact area between the conductive plug and the landing pad, reducing the contact resistance, improving the signal transmission quality and reducing the corresponding power consumption.

An embodiment of the present disclosure further provides a semiconductor structure, which may be manufactured by the above-mentioned method for manufacturing a semiconductor structure.

Referring to FIG. 28, the semiconductor structure includes: a substrate 20 and a plurality of discrete bit line structures (not shown) on the substrate 20, a conductive plug 25 being arranged between each adjacent bit line structures, a top surface of the conductive plug 25 being lower than or flush with that of the bit line structure; and a landing pad 27, the landing pad covering at least the top surface and part of side wall surfaces of the conductive plug 25.

In some embodiments of the present disclosure, in a direction perpendicular to the surface of the substrate 20, the orthographic projection of the landing pad 27 partially overlaps with the orthographic projection of the bit line structure.

The bit line structure includes an initial bit line structure 21, isolation side walls 22 on two sides of the initial bit line structure 21, and a top isolation layer 26. The top isolation layer 26 covers the top surface of the initial bit line structure 21 and the top surface of the isolation side wall 22. In the direction perpendicular to the surface of the substrate 20, the orthographic projection of the landing pad 27 at least partially overlaps the orthographic projection of the isolation side wall 22.

There is an air gap 224 in the isolation side wall 22, the top isolation layer 26 blocks the air gap 224, and a bottom surface of the landing pad 27 is higher than that of the top isolation layer 26.

In some embodiments of the present disclosure, the initial bit line structure 21 includes a metal conductive layer 214 and a top dielectric layer 215 located on the metal conductive layer 214 away from the surface of the substrate 20. In the direction perpendicular to the surface of the substrate 20, the top dielectric layer 215 has a thickness of 20 nm to 100 nm, such as 30 nm, 50 nm, or 70 nm.

In some embodiments of the present disclosure, the landing pad 27 has a projection overlapping portion. In the direction perpendicular to the surface of the substrate 20, the orthographic projection of the projection overlapping portion is located within the orthographic projection of the bit line structure, and the surface of the projection overlapping portion facing the substrate 20 is a flat surface.

In some embodiments of the present disclosure, the landing pad not only covers the top surface of the conductive plug, but also covers part of the side wall surfaces of the conductive plug, which is beneficial to increasing the contact area between the conductive plug and the landing pad, reducing the contact resistance, improving the signal transmission quality and reducing the corresponding power consumption.

A person skilled in the art would easily conceive of other embodiments of the present disclosure after considering the disclosure of the description and practice. The present disclosure is intended to cover any variations, uses or adaptive changes of the present disclosure. These variations, uses or adaptive changes follow the general principle of the present disclosure and comprise common general knowledge or conventional technical means in the technical field that are not disclosed in the present disclosure. The description and the embodiments are merely regarded as exemplary, and the real scope and spirit of the present disclosure are pointed out by the following claims.

It should be understood that the present disclosure is not limited to the precise structure described above and shown in the drawings, and various modifications and changes can be made without departing from its scope. The scope of the present disclosure is only limited by the appended claims.

### INDUSTRIAL APPLICABILITY

The embodiments of the present disclosure provide a semiconductor structure and a method for manufacturing the same, in which the landing pad not only covers the top surface of the conductive plug, but also covers part of the side wall surfaces of the conductive plug, thereby increasing the contact area between the conductive plug and the landing pad, reducing the contact resistance, then improving the signal transmission quality and reducing the corresponding power consumption.

1. A semiconductor structure, comprising:
a substrate and a plurality of discrete bit line structures disposed on the substrate, a conductive plug being arranged between each adjacent bit line structures, a top surface of the conductive plug being lower than or flush with top surfaces of the bit line structures; and
landing pads, one of the landing pads covering at least the top surface and part of side wall surfaces of the conductive plug.

2. The semiconductor structure according to claim 1, wherein in a direction perpendicular to a surface of the substrate, an orthographic projection of one of the landing pads partially overlaps an orthographic projection of one of the bit line structures.

3. The semiconductor structure according to claim 2, wherein each of the bit line structures comprises an initial bit line structure, isolation side walls on two sides of the initial bit line structure, and a top isolation layer; the top isolation layer covers a top surface of the initial bit line structure and top surfaces of the isolation side walls; in the direction perpendicular to the surface of the substrate, the orthographic projection of one of the landing pads at least partially overlaps an orthographic projection of one of the isolation side walls.

4. The semiconductor structure according to claim 3, wherein there is an air gap in each of the isolation side walls, the top isolation layer blocks the air gap, and a bottom surface of each of the landing pads is higher than a bottom surface of the top isolation layer.

5. The semiconductor structure according to claim 3, wherein the initial bit line structure comprises a metal conductive layer and a top dielectric layer located on the metal conductive layer away from the surface of the substrate; in the direction perpendicular to the surface of the substrate, the top dielectric layer has a thickness of 20 nm to 100 nm.

6. The semiconductor structure according to claim 2, wherein each of the landing pads has a projection overlapping portion; in the direction perpendicular to the surface of the substrate, an orthographic projection of the projection overlapping portion is located within the orthographic projection of one of the bit line structures; and a surface of the projection overlapping portion facing the substrate is a flat surface.

7. A method for manufacturing a semiconductor structure, comprising:
providing a substrate and a plurality of discrete bit line structures disposed on the substrate, a conductive plug being arranged between each adjacent bit line structures, a top surface of the conductive plug being lower than or flush with top surfaces of the bit line structures;
exposing part of side wall surfaces of the conductive plug; and
forming landing pads, one of the landing pads covering at least the top surface and part of the side wall surfaces of the conductive plug.

8. The method for manufacturing the semiconductor structure according to claim 7, wherein the exposing part of side wall surfaces of the conductive plug comprises: forming a mask layer with an opening on each of the bit line structures, the opening exposing part of the top surface of one of the bit line structures; and performing an etching process to etch the bit line structures.

9. The method for manufacturing the semiconductor structure according to claim 8, wherein each of the bit line structures comprises isolation side walls and a top isolation layer covering top surfaces of the isolation side walls; in a direction perpendicular to a surface of the substrate, an orthographic projection of the top isolation layer removed by the etching process at least partially overlaps orthographic projections of the isolation side walls.

10. The method for manufacturing the semiconductor structure according to claim 9, wherein an air gap is provided in each of the isolation side walls, the top isolation layer blocks a top opening of the air gap, and the etching process does not expose the air gap.

11. The method for manufacturing the semiconductor structure according to claim 7, the method for manufacturing further comprises forming the bit line structures, and the forming the bit line structures comprises: providing initial bit line structures, top surfaces of the initial bit line structures being higher than or flush with top surface of the conductive plug; and etching the initial bit line structures back.

12. The method for manufacturing the semiconductor structure according to claim 11, before etching the initial bit line structures back, the method further comprises:
depositing a first side wall film and a first sacrificial film in sequence, and depositing a second side wall film to form initial isolation side walls;
depositing a second sacrificial layer, and forming bit line isolation trenches in the second sacrificial layer;
filling dielectric material to form a bit line isolation film;
removing the bit line isolation film on a top of the second sacrificial layer, and forming bit line isolation layers;
removing the second sacrificial layer, and removing the first side wall film and the second side wall film at bottoms of grooves between adjacent initial bit line structures, and forming capacitor contact holes;
filling the capacitor contact holes with conductive material, and forming a conductive film; and
performing a planarization process on the conductive film, and forming the conductive plugs.

13. The method for manufacturing the semiconductor structure according to claim 12, wherein the etching the initial bit line structures back comprises:
etching the initial bit line structures and the initial isolation side walls back, so that the top surfaces of the initial bit line structures and top surfaces of the initial isolation side walls are lower than the top surfaces of the conductive plugs.

14. The method for manufacturing the semiconductor structure according to claim 12, after etching the initial bit line structures back, the method further comprises:
removing the first sacrificial film to form air gaps; and
forming a top isolation film that blocks top openings of the air gaps.

15. The method for manufacturing the semiconductor structure according to claim 14, after forming a top isolation film that blocks top openings of the air gaps, the method further comprises:
forming a second mask layer;
etching the top isolation film through the second mask layer; and
forming top isolation layers exposing the top surface and part of the side wall surfaces of the conductive plug.

16. The method for manufacturing the semiconductor structure according to claim 15, the forming landing pads, one of the landing pads covering at least the top surface and part of the side wall surfaces of the conductive plug, comprises:
form a landing film;
forming a third mask layer; and
etching the landing film through the third mask layer, forming the landing pads, one of the landing pads covering at least the top surface and part of the side wall surfaces of the conductive plug.
